(19) United States
(12) Patent Application Publication
(10) Pub. No.: US 2017/0285378 A1
(43) Pub. Date: Oct. 5, 2017

(54) LARGE SUBSTRATE AND METHOD OF MANUFACTURING LARGE SUBSTRATE

(71) Applicant: SEIKO EPSON CORPORATION, Tokyo (JP)

(72) Inventor: Yasuhiro TAKEUCHI, Shiojiri-shi (JP)

(73) Assignee: SEIKO EPSON CORPORATION, Tokyo (JP)

(21) Appl. No.: 15/467,381

(22) Filed: Mar. 23, 2017

(30) Foreign Application Priority Data
Mar. 30, 2016 (JP) 2016-067496

(51) Int. Cl. G02F 1/1339; G02F 1/1333; G02F 1/1341; H01L 27/12

(52) U.S. Cl. CPC G02F 1/1339; H01L 27/1248; H01L 27/124; G02F 1/133345; G02F 1/1341; G02F 2001/13415; G02F 1/133512

(57) ABSTRACT

A large substrate includes, in which the sealing material includes at least a first sealing material disposed between an element substrate and a counter substrate in a central region of the first large substrate and the second large substrate, and a second sealing material disposed between the element substrate and the counter substrate in an outside region of the first large substrate and the second large substrate, and when a cell gap in a display region of the element substrate and the counter substrate in the central region and the outside region is set to be constant, a gap amount of a region in which the first sealing material is provided and a gap amount of at least a portion of a region in which the second sealing material is provided are different from each other.

### BACKGROUND

### 1. Technical Field

The present invention relates to a large substrate and a method of manufacturing the large substrate.

### 2. Related Art

A large substrate is configured such that a first large substrate 501 on which a plurality of element substrates are mounted, and a second large substrate 502 on which a plurality of counter substrates are mounted are bonded to each other via a sealing material 14, as illustrated in FIG. 23. Further, a large substrate 500 includes liquid crystal 15a which is sealed by being surrounded by the sealing material 14 between the first large substrate 501 and the second large substrate 502.

A method of manufacturing the large substrate 500 includes coating the first large substrate 501 with the sealing material 14, adding the liquid crystal 15a dropwise into a frame of the sealing material 14, and then sealing the liquid crystal 15a by overlapping the second large substrate 502 (a so-called one drop fill (ODF) method). Further, it is possible to form a plurality of liquid crystal devices 100 by cutting the large substrate 500 into a chip size, for example, as disclosed in JP-A-2015-138167.

However, due to variation in density of the sealing material 14 (the number of chips, presence or absence of filling of the liquid crystal 15a, or the like) in a first region (a central region) and a second region (an outside region) of the large substrate 500, there is a problem in that the sealing material 14 may collapse unevenly as illustrated in FIG. 23, and thus a shape of a gap between the first region and the second may be unevenly formed. Specifically, the density of the sealing material 14 is high in the first region, and thus the sealing material 14 is less likely to collapse; whereas, the density of the sealing material 14 is low in the second region, and thus the sealing material 14 is likely to collapse. With this, when the liquid crystal devices 100 (chips) obtained by cutting the large substrate 500 are used, there is a problem in that the display quality (transmittance, display unevenness, or the like) is deteriorated.

### SUMMARY

The invention can be realized in the following aspects or application examples.

### APPLICATION EXAMPLE 1

According to this application example, there is provided a large substrate including a first large substrate which is provided with a plurality of first substrates; a second large substrate which is provided with a plurality of second substrates; a sealing material which is disposed between the first large substrate and the second large substrate which are disposed to face each other; and a liquid crystal layer which is disposed by being surrounded by the sealing material, in which in a certain region, a gap amount of a display region and a gap amount of a region in which the sealing material is provided are different from each other on the first substrate and the second substrate.

According to the application example, the gap amount only in a certain region of the first substrate and the display region of the second substrate (in other words, chips) and the gap amount of the region in which the sealing material is provided are different from each other, and thus when the first large substrate and the second large substrate are bonded to each other, even in a case where the sealing material has collapsed unevenly due to variation in density of the sealing material or the presence or absence of a liquid crystal layer, it is possible to prevent a cell gap (a shape of a gap) from being unevenly formed in the display region.

### APPLICATION EXAMPLE 2

In the large substrate according to the application example, it is preferable that the gap amount of the display region and the gap amount of the region in which the sealing material be provided be different from each other on all of the first large substrate and the second large substrate, and the gap amount of the region, in which the sealing material is provided, in the certain region be different from of the gap amount of the region, in which the sealing material is provided, in a region other than the certain region.

According to the application example, in the certain region and the region other than the certain region, the gap amounts of the regions, in which the sealing material is provided, of the first substrate and the second substrate (in other words, chips) are different from each other, and thus when the first large substrate and the second large substrate are bonded to each other, and thus when the first large substrate and the second large substrate are bonded to each other, even in a case where the sealing material has collapsed unevenly due to the density difference of the sealing material or the presence or absence of the liquid crystal layer, it is possible to prevent the cell gap (the shape of the gap) from being unevenly formed in the display region.

### APPLICATION EXAMPLE 3

According to this application example, there is provided a large substrate including a first large substrate which is provided with a plurality of first substrates; a second large substrate which is provided with a plurality of second substrates; a sealing material which is disposed between the first large substrate and the second large substrate which face each other; and a liquid crystal layer which is disposed by being surrounded by the sealing material, in which the sealing material includes at least a first sealing material which is disposed between the first substrate and the second substrate in a central region of the first large substrate and the second large substrate, and a second sealing material which is disposed between the first substrate and the second substrate in an outside region of the first large substrate and the second large substrate, and when a cell gap in a display region of the first substrate and the second substrate in the central region and the outside region is set to be constant, a gap amount of a region in which the first sealing material is provided and a gap amount of at least a portion of a region in which the second sealing material is provided are different from each other.

According to the application example, the gap amounts of the sealing materials (the first sealing material and the second sealing material) in the central region and the outside region of the large substrate are different from each other, and thus when the first large substrate and the second large substrate are bonded to each other, even in a case where the sealing material has collapsed unevenly due to the density difference of the sealing material or the presence or absence of the liquid crystal layer, it is possible to prevent the cell gap (the shape of the gap) from being unevenly formed in the display regions between the liquid crystal device in the central region and the liquid crystal device in the outside region.

### APPLICATION EXAMPLE 4

In the large substrate according to the application example, it is preferable that the gap amount be formed by providing a step in at least one of the first substrate and the second substrate.

According to the application example, the gap amounts are differentiated from each other by providing the step in the region, in which the sealing material is provided, of the substrates (the first substrate and the second substrate), and thus it is possible to differentiate the gap amounts from each other in a relatively easy manner.

### APPLICATION EXAMPLE 5

In the large substrate according to the application example, it is preferable that the step include a first step which is provided in the region in which the first sealing material is disposed, and a second step which is provided in the region in which the second sealing material is disposed, and an amount of the first step be larger than that of the second step.

According to the application example, the amount of the first step is larger than that of the second step, and thus, for example, even in a case where the first sealing material is less likely to collapse as compared with the second sealing material due to the density difference of the sealing material or the presence or absence of the liquid crystal layer, it is possible to prevent the cell gap of the liquid crystal device of the central region and the cell gap of the liquid crystal device in the outside region from being different.

### APPLICATION EXAMPLE 6

In the large substrate according to the application example, it is preferable that the step include a first step which is provided in the region in which the first sealing material is disposed, and a second step which is provided in the region in which the second sealing material is disposed, and an amount of the first step be smaller than that of the second step.

According to the application example, the amount of the first step is smaller than that of the second step, and thus, for example, even in a case where the first sealing material is less likely to collapse as compared with the second sealing material due to the density difference of the sealing material or the presence or absence of the liquid crystal layer, it is possible to prevent the cell gap of the liquid crystal device of the central region and the cell gap of the liquid crystal device in the outside region from being different.

### APPLICATION EXAMPLE 7

In the large substrate according to the application example, it is preferable that the first large substrate and the second large substrate include a sealing region in which the first sealing material and the second sealing material are provided, and a display region which is surrounded by the sealing region, and a film thickness of an insulating layer in the sealing region be smaller than a film thickness of an insulating layer in the display region.

According to the application example, the gap amount is adjusted by setting the film thickness of the insulating layer in the sealing region to be small, and thus it is possible to set the cell gap amount to be relatively small. Further, as compared with a case where the display region is formed to be small, it is possible to prevent the display region from being damaged, and prevent the display quality from being deteriorated.

### APPLICATION EXAMPLE 8

In the large substrate according to the application example, it is preferable that the first large substrate and the second large substrate include a sealing region in which the first sealing material and the second sealing material are provided, and a display region which is surrounded by the sealing region, and a film thickness of an insulating layer in the display region be smaller than a film thickness of an insulating layer of the sealing region.

According to the application example, the gap amount is adjusted by setting the film thickness of the insulating layer in the display region to be small, and thus it is possible to set the film thickness of the insulating layer in the display region to be small. Accordingly, it is possible to improve the transmittance in the display region.

### APPLICATION EXAMPLE 9

In the large substrate according to the application example, it is preferable that the first large substrate and the second large substrate include a sealing region in which the first sealing material and the second sealing material are provided, and a display region which is surrounded by the sealing region, and a film thickness of an insulating layer in a first sealing region in which at least the first sealing material is provided be smaller than a film thickness of an insulating layer in the display region.

According to the application example, the film thickness of at least the insulating layer of the first sealing region of the central region may be small, for example, and the step may not be provided in the outside region. With this, the step may be formed only in the central region, and thus it is possible to minimize costs when forming the step. In addition, the region for forming the step may be small, and thus it is possible to prevent the gap amount from being different.

### APPLICATION EXAMPLE 10

In the large substrate according to the application example, it is preferable that in the first large substrate and the second large substrate, the amount of the step gradually changes from the central region to the outside region.

According to the application example, the amount of the steps gradually changes, and thus it is possible to change the step in accordance with the deformation of the large substrate, and possible to make the cell gap uniform in the entire large substrate.

### APPLICATION EXAMPLE 11

According to this application example, there is provided a method of manufacturing a large substrate, the method including coating a first large substrate which is provided with a plurality of first substrates with a sealing material; adding a liquid crystal dropwise into a region surrounded by the sealing material; bonding the first large substrate and a second large substrate which is provided with a plurality of second substrates to each other; and forming a step in at least one of the first substrate and the second substrate before coating the first large substrate with the sealing material.

According to the application example, the step is formed on the large substrate so as to differentiate the gap amounts, and thus when the first large substrate and the second large substrate are bonded to each other, even in a case where the sealing material has collapsed unevenly due to the density difference of the sealing material or the presence or absence of a liquid crystal layer, it is possible to prevent the cell gap (the shape of the gap) from being unevenly formed in the display region of the liquid crystal device.

### APPLICATION EXAMPLE 12

According to this application example, there is provided a method of manufacturing a large substrate, the method including coating a central region of a first large substrate which is provided with a plurality of first substrates with a first sealing material; coating an outside region of the first large substrate with a second sealing material; adding a liquid crystal dropwise into a region surrounded by the first sealing material and the second sealing material; bonding the first large substrate and a second large substrate which is provided with a plurality of second substrates to each other; and forming a step in at least one of the first substrate and the second substrate before coating the first large substrate with the first sealing material such that a gap amount of a region which is coated with the first sealing material and a gap amount of at least a portion of the region which is coated with the second sealing material are different from each other in a case where a cell gap in a display region of the first substrate and the second substrate is set to be constant.

According to the application example, the gap amounts of the sealing materials (the first sealing material and the second sealing material) in the central region and the outside region of the large substrate are differentiated from each other, and thus when the first large substrate and the second large substrate are bonded to each other, even in a case where the sealing material has collapsed unevenly due to the density difference of the sealing material or the presence or absence of the liquid crystal layer, it is possible to prevent the cell gap (the shape of the gap) from being unevenly formed in the display regions between the liquid crystal device in the central region and the liquid crystal device in the outside region.

### APPLICATION EXAMPLE 13

In the method of manufacturing a large substrate according to the application example, it is preferable that in the forming of the step, the step be formed in at least one substrate of the first substrate and the second substrate by removing a portion of the region which is coated with the first sealing material and the second sealing material.

According to the application example, the gap amount is adjusted by setting the film thickness of the insulating layer in the sealing region to be small, and thus it is possible to set the cell gap amount to be relatively small. Further, as compared with a case where the display region is formed to be small, it is possible to prevent the display region from being damaged, and prevent the display quality from being deteriorated.

### APPLICATION EXAMPLE 14

In the method of manufacturing a large substrate according to the application example, it is preferable that in the forming of the step, the step be formed in at least one substrate of the first substrate and the second substrate by removing a portion of the display region.

According to the application example, the gap amount is adjusted by setting the film thickness of the insulating layer in the display region to be small, and thus it is possible to set the film thickness of the insulating layer in the display region to be small. Accordingly, it is possible to improve the transmittance in the display region.

### BRIEF DESCRIPTION OF THE DRAWINGS

The invention will be described with reference to the accompanying drawings, wherein like numbers reference like elements.

FIG. 1 is a perspective view illustrating a configuration of a large substrate including a plurality of liquid crystal devices.

FIG. 2 is a plan view schematically illustrating the large substrate illustrated in FIG. 1 when seen from above.

FIG. 3 is an enlarged plan view illustrating an enlarged A portion of the large substrate as illustrated in FIGS. 1 and 2.

FIG. 4 is a plan view schematically illustrating a configuration of the liquid crystal device.

FIG. 5 is a schematic sectional view taken along line V-V of the liquid crystal device illustrated in FIG. 4.

FIG. 6 is an equivalent circuit diagram illustrating an electrical configuration of the liquid crystal device.

FIG. 7 is a schematic sectional view mainly illustrating a structure of a pixel of the liquid crystal device.

FIG. 8 is sectional view schematically and specifically illustrating a structure around a sealing material in the liquid crystal device.

FIG. 9 is a schematic sectional view taken along line IX-IX of the large substrate as illustrated in FIG. 2.

FIG. 10 is a flowchart illustrating a method manufacturing a large substrate (a liquid crystal device) in order of steps.

FIG. 11 is a schematic sectional view illustrating a manufacturing method among the methods of manufacturing a large substrate.

FIG. 12 is a schematic sectional view illustrating a manufacturing method among the methods of manufacturing a large substrate.

FIG. 13 is a schematic sectional view illustrating a manufacturing method among the methods of manufacturing a large substrate.

FIG. 14 is a schematic sectional view illustrating a manufacturing method among the methods of manufacturing a large substrate.

FIG. 15 is a schematic sectional view illustrating a manufacturing method among the methods of manufacturing a large substrate.

FIG. 16 is a schematic sectional view illustrating a manufacturing method among the methods of manufacturing a large substrate.

FIG. 17 is a schematic sectional view illustrating a manufacturing method among the methods of manufacturing a large substrate.

FIG. 18 is a schematic sectional view illustrating a manufacturing method among the methods of manufacturing a large substrate.

FIG. 19 is a diagram schematically illustrating a configuration of a projector as an electronic apparatus.

FIG. 20 is a schematic sectional view taken along line XX-XX of the large substrate as illustrated in FIG. 2, in a second embodiment.

FIG. 21 is a schematic sectional view taken along line XXI-XXI of the large substrate as illustrated in FIG. 2, in a third embodiment.

FIG. 22 is a plan view schematically illustrating the large substrate when seen from above in a modification example.

FIG. 23 is a sectional view schematically illustrating a structure of a large substrate in the related art.

### DESCRIPTION OF EXEMPLARY EMBODIMENTS

Hereinafter, embodiments of the invention will be described in detail with reference to the drawings. Note that, the drawings to be referred are displayed by being appropriately enlarged or reduced such that parts to be described are in a recognizable state.

In addition, in the following embodiments, a case of the expression “on a substrate” means a case of being disposed so as to be in contact with an upper surface of the substrate, a case where disposed on the substrate via other components, or a case where a portion is disposed to be in contact with the upper surface of the substrate and a portion is disposed on the substrate via other components.

In the embodiment, an active matrix type liquid crystal device which is provided with a thin film transistor as a switching element of a pixel is exemplified. The liquid crystal device can be preferably used as an optical modulation element (a liquid crystal light bulb) of a projection type apparatus (a liquid crystal projector), for example.

### First Embodiment

### Configuration of Large Substrate

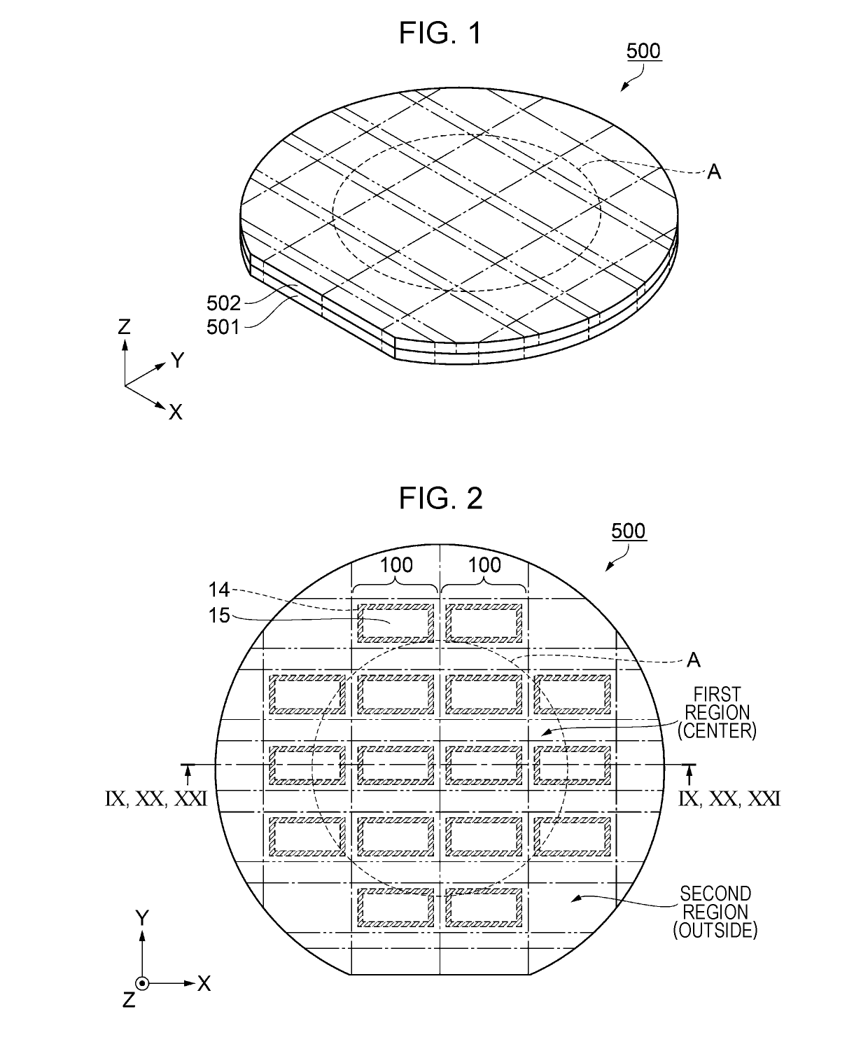

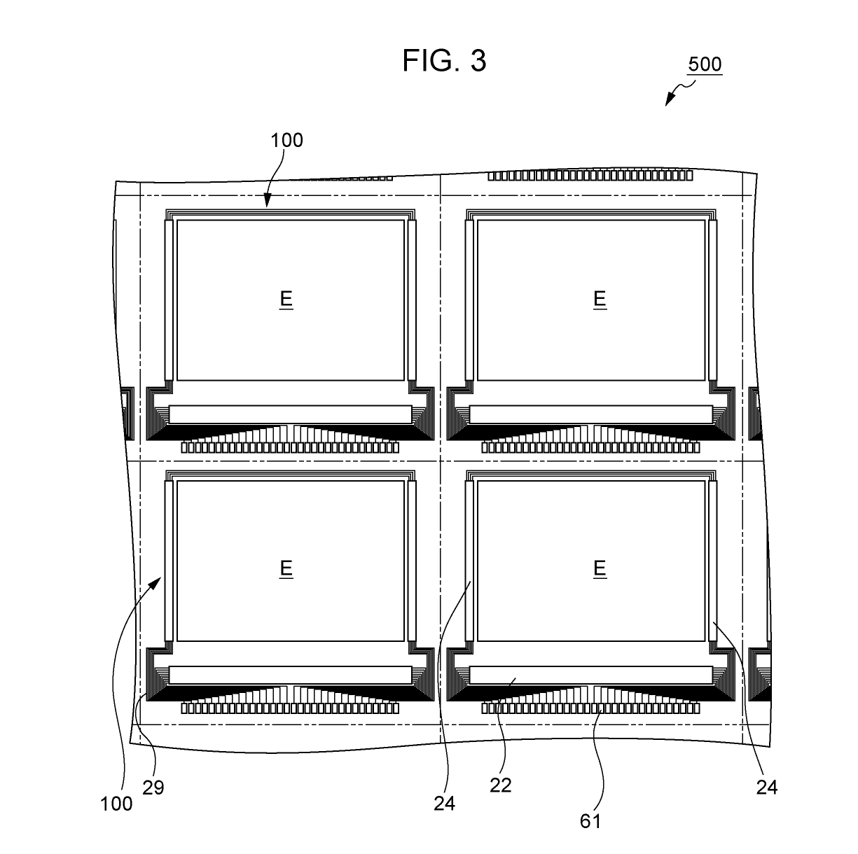

FIG. 1 is a perspective view illustrating a configuration of a large substrate including a plurality of liquid crystal devices. FIG. 2 is a plan view schematically illustrating the large substrate illustrated in FIG. 1 when seen from above. FIG. 3 is an enlarged plan view illustrating an enlarged A portion of the large substrate as illustrated in FIGS. 1 and 2. Hereinafter, the configuration of the large substrate will be described with reference to FIGS. 1 to 3.

As illustrated in FIGS. 1 and 2, a large substrate 500 is obtained by bonding a first large substrate 501 and a second large substrate 502 to each other via a sealing material 14. A liquid crystal layer 15 is disposed in an area surrounded by the sealing material 14. On the large substrate 500, a plurality of liquid crystal devices 100 are mounted to each other in a matrix shape on the substrate.

The size of each of the first large substrate 501 and the second large substrate 502 is, for example, 8 inches. The thickness of each of the first large substrate 501 and the second large substrate 502 is, for example, 1.2 mm. A material for the first large substrate 501 and the second large substrate 502 is, for example, quartz.

As illustrated in FIG. 3, in the respective liquid crystal devices 100, a data line drive circuit 22, a scanning line drive circuit 24, and an external connection terminal portion 61 are formed in the vicinity of display region E. The data line drive circuit 22 and the scanning line drive circuit 24, and the external connection terminal portion 61 are electrically connected to each other via a wiring 29.

### Configuration of Liquid Crystal Device

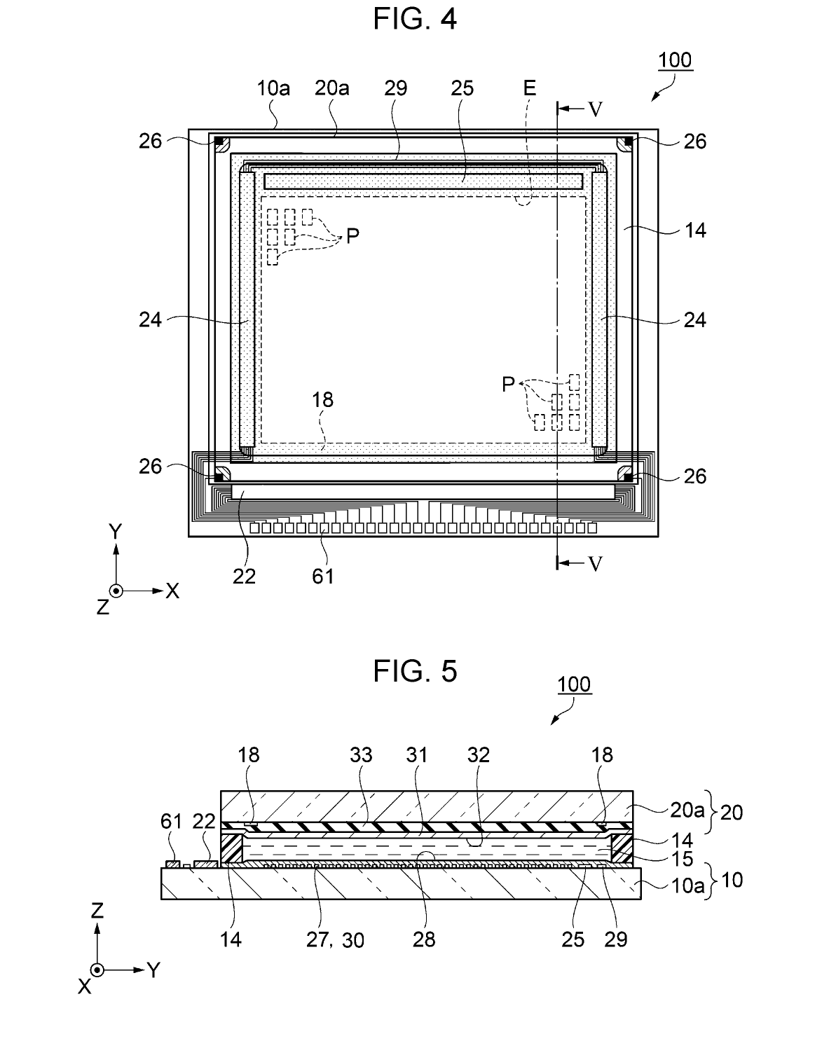

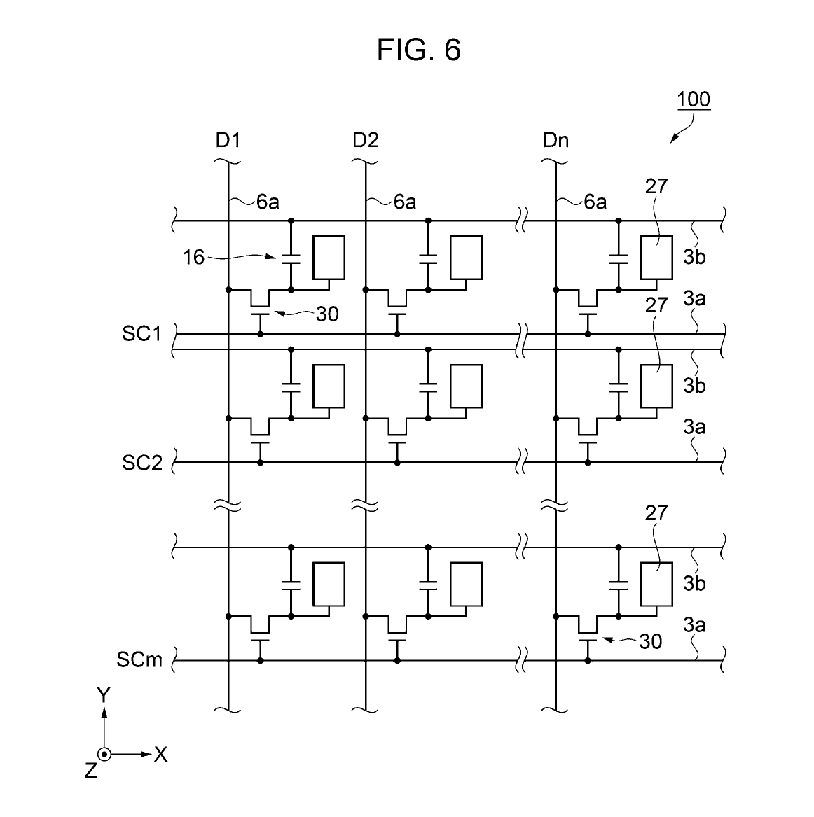

FIG. 4 is a plan view illustrating a configuration of the liquid crystal device which can cut the large substrate. FIG. 5 is a schematic sectional view taken along line V-V of the liquid crystal device illustrated in FIG. 4. FIG. 6 is an equivalent circuit diagram illustrating an electrical configuration of the liquid crystal device. Hereinafter, the configuration of the liquid crystal device will be described with reference to FIGS. 4 to 6.

As illustrated in FIGS. 4 and 5, the liquid crystal device 100 of the embodiment includes an element substrate 10 as a first substrate and a counter substrate 20 as a second substrate which face each other, and the liquid crystal layer 15 which is interposed between a pair of the element substrate and the counter substrate. As a first material 10a for constituting the element substrate 10, and a second substrate 20a for constituting the counter substrate 20, for example, a transparent substrate such as a glass substrate or quartz substrate is used.

The element substrate 10 is larger than the counter substrate 20, and both substrates are bonded to each other via the sealing material 14 which is disposed along the outer periphery of the counter substrate 20. The liquid crystal layer 15 is formed by sealing a liquid crystal having positive or negative dielectric anisotropy in the gap between both of the substrates.

As the sealing material 14, for example, an adhesive such as a thermosetting or ultraviolet-curable epoxy resin is employed. The display region E in which a plurality of pixels P contributing to the display is provided in the inside of the sealing material 14.

A data line drive circuit 22 is provided between the sealing material 14 along a first side portion of the element substrate 10 and the first side portion. In addition, an inspection circuit 25 is provided between the sealing material 14 along another first side portion facing the aforementioned first side portion and the display region E. Further, a scanning line drive circuit 24 is provided between the sealing material 14 along another second side portion which is orthogonal to and faces the aforementioned first side portion and the display region E. A plurality of the wirings 29 which connects two of the scanning line drive circuits 24 are provided between the sealing material 14 along another first side portion facing the aforementioned first side portion and the inspection circuit 25.

In the inside of the sealing material 14 which is disposed in a frame shape on the counter substrate 20 side, a light shielding film 18 (a parting portion) is provided in the frame shape likewise. The light shielding film 18 is formed of, for example, metal having light reflectivity or a metal oxide, and the inside of the light shielding film 18 becomes the display region E including the plurality of pixels P. As the light shielding film 18, tungsten silicide (WSi) can be used, for example.

The wiring which connects these data line drive circuit 22 and the scanning line drive circuit 24 to each other is connected to a plurality of external connection terminal portions 61 which are arranged along the first side portion. Hereinafter, the direction along the first side portion is referred to as an X direction, and the direction along another second side portion which is orthogonal to and faces the first side portion is referred to as a Y direction.

As illustrated in FIG. 5, a thin film transistor (hereinafter, referred to as “a transistor 30”) which is a translucent pixel electrode 27 and a switching element provided for each pixel P, a signal wiring (not shown), and a first alignment film 28 which covers the thin film transistor and the signal wiring are formed on the surface of the first material 10a on the liquid crystal layer 15 side.

In addition, a light shielding structure (not shown) in which light is incident on the semiconductor layer in the transistor 30 so as to prevent a switching operation from being unstable is employed. The element substrate 10 in the invention includes at least the pixel electrode 27, the transistor 30, and the first alignment film 28.

The light shielding film 18, an insulating layer 33 which is formed to cover the light shielding film, a counter electrode 31 which is provided to cover the insulating layer 33, and a second alignment film 32 which covers the counter electrode 31 are provided on the surface of the counter substrate 20 on the liquid crystal layer 15 side. The counter substrate 20 of the invention includes at least the light shielding film 18, the counter electrode 31, and the second alignment film 32.

As illustrated in FIG. 4, the light shielding film 18 is provided in a position which overlaps the scanning line drive circuit 24 and the inspection circuit 25 in a plan view while surrounding the display region E. With this, the light incident on the peripheral circuit including these driving circuits is shielded from the counter substrate 20 side, and thereby the peripheral circuit is prevented from being malfunctioned due to the light. In addition, unnecessary stray light is shielded not to be incident on the display region E so as to secure high contrast in the display of the display region E.

The insulating layer 33 is formed of, for example, an inorganic material such as oxide silicon, has light transmissivity, and is provided so as to cover the light shielding film 18. Examples of a method of forming such an insulating layer 33 include a method of forming a film by using, for example, a plasma chemical vapor deposition (CVD) method.

The counter electrode 31 is formed of, for example, a transparent conductive film such as indium tin oxide (ITO), covers the insulating layer 33, and is electrically connected to the wiring on the element substrate 10 side by vertical conduction portions 26 provided at four corners of the counter substrate 20 as illustrated in FIG. 4.

The first alignment film 28 which covers the pixel electrode 27 and the second alignment film 32 which covers the counter electrode 31 are selected based on optical design of the liquid crystal device 100. Examples of the first alignment film 28 and the second alignment film 32 include an inorganic alignment film which is obtained by forming a film with an inorganic material such as oxide silicon (SiOx) through a vapor phase deposition method, and is substantially vertically aligned with respect to liquid crystal molecule having negative dielectric anisotropy.

Such a liquid crystal device 100 is, for example, a transmissive type, and normally white mode optical design in which transmittance of the pixel P when a voltage is not applied is greater than transmittance of the pixel P when the voltage is applied, and normally black mode optical design in which transmittance of the pixel P when the voltage is not applied is smaller than transmittance of the pixel P when the voltage is applied. Each of polarizing elements is used by being disposed on the incident side and the emitted side of the light in accordance with the optical design.

As illustrated in FIG. 6, the liquid crystal device 100 includes a plurality of scanning lines 3a and a plurality of data lines 6a, and a plurality of capacity lines 3b which are insulated from and orthogonal to each other at least in the display region E. For example, the direction to which the scanning line 3a extends is the X direction and the direction to which the data line 6a extends is the Y direction.

A pixel circuit of the pixel P is formed of the scanning line 3a, the data line 6a, and the capacity line 3b with the pixel electrode 27, the transistor 30, and a capacity element 16 which are provided in a region divided by the signal lines of the aforementioned lines.

The scanning line 3a is electrically connected to a gate of the transistor 30, and the data line 6a is electrically connected to the source drain region of the transistor 30 on the data line side. The pixel electrode 27 is electrically connected to the source drain region of the transistor 30 on the pixel electrode side.

The data line 6a is connected to a data line drive circuit 22 (refer to FIG. 4), and supplies image signals D1, D2, . . . , and Dn which are supplied from the data line drive circuit 22 to each of the pixels P. The scanning line 3a is connected to the scanning line drive circuit 24 (refer to FIG. 4), and supplies scanning signals SC1, SC2, . . . , and SCm supplied from the scanning line drive circuit 24 to each of the pixels P.

The image signals D1 to Dn which are supplied from the data line drive circuit 22 to the data line 6a may be line-sequentially supplied in this order, and may be supplied for each group with respect to the plurality of data lines 6a which are adjacent to each other. The scanning line drive circuit 24 line-sequentially supplies the scanning signals SC1 to SCm to the scanning line 3a at a predetermined timing in a pulse.

When the transistor 30 which is the switching element is in an on-state for a certain periods of time by inputting the scanning signals SC1 to SCm, the liquid crystal device 100 has a configuration in which the image signals D1 to Dn supplied from the data line 6a are written into the pixel electrode 27 at a predetermined timing. In addition, the image signals D1 to Dn at a predetermined level which are written into the liquid crystal layer 15 via the pixel electrode 27 are held for a certain periods of time between the pixel electrode 27 and the counter electrode 31 which are disposed to face each other via the liquid crystal layer 15.

In order to prevent the held image signals D1 to Dn from being leaked, the capacity element 16 is connected to a liquid crystal capacity formed between the pixel electrode 27 and the counter electrode 31 in parallel. The capacity element 16 is provided between the source drain region of the transistor 30 on the pixel electrode side and the capacity line 3b. The capacity element 16 includes a dielectric layer between two capacity electrodes.

### Configuration of Pixel Forming Liquid Crystal Device

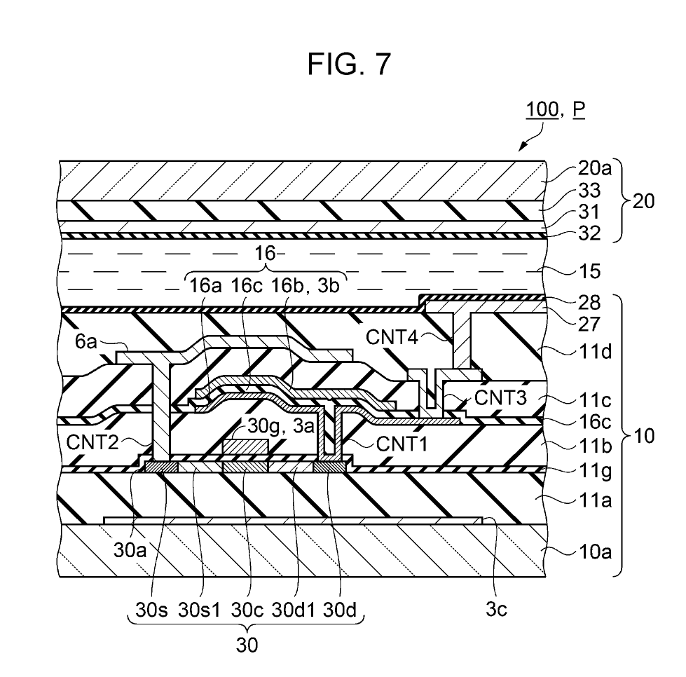

Next, the configuration of the pixel will be described with reference to FIG. 7. FIG. 7 is a schematic sectional view mainly illustrating a structure of a pixel of the liquid crystal device. Note that, FIG. 7 illustrates cross-sectional position relationship of each of the components which are represented in presentable measure.

As illustrated in FIG. 7, the pixel P of the liquid crystal device 100 is provided with the element substrate 10 and the counter substrate 20 which is disposed to face the element substrate 10. The first material 10a for constituting the element substrate 10 is, for example, a quartz substrate.

As illustrated in FIG. 7, a light shielding layer 3c formed of, for example, tungsten silicide (WSi) is disposed on the first material 10a. The light shielding layer 3c is patterned in a matrix shape in a plan view, and defines an opening region of each of the pixels P. A first insulating layer 11a formed of oxide silicon or the like is formed on the light shielding layer 3c.

The transistor 30, the scanning line 3a, and the like are formed on the first insulating layer 11a. The transistor 30 has, for example, a lightly doped drain (LDD) structure, and includes a semiconductor layer 30a formed of polysilicon (high-purity of polycrystalline silicon) or the like, a gate insulating layer 11g formed on the semiconductor layer 30a, and a gate electrode 30g formed of the polysilicon film formed on the gate insulating layer 11g. The scanning line 3a also serves as a gate electrode 30g.

For example, an N-type impurity ion such as phosphorus (P) ion is poured into the semiconductor layer 30a so as to form an N-type transistor 30. Specifically, the semiconductor layer 30a is provided with a channel region 30c, a data line side LDD region 30s1, a data line side source drain region 30s, a pixel electrode side LDD region 30d1, and a pixel electrode side source drain region 30d.

The channel region 30c is doped with a p-type impurity ion such as a boron (B) ion. Other regions (30s1, 30s, 30d1, and 30d) are doped with an N-type impurity ion such as a phosphorus (P) ion. As such, the transistor 30 is formed as an N-type transistor.

A second insulating layer 11b formed of oxide silicon is formed on the gate electrode 30g and the gate insulating layer 11g. The capacity element 16 is provided on the second insulating layer 11b. Specifically, the capacity element 16 is formed in such a manner that a first capacity electrode 16a as a pixel potential side capacity electrode which is electrically connected to the pixel electrode side source drain region 30d of the transistor 30 and the pixel electrode 27 and a portion of the capacity line 3b (a second capacity electrode 16b) as a fixed potential side capacity electrode are disposed to face each other via an dielectric film 16c.

The dielectric film 16c is, for example, a silicon nitride film. The second capacity electrode 16b (the capacity line 3b) is formed by stacking elemental metal, an alloy, metal silicide and poly-silicide which contains at least one of high-melting-point metal such as titanium (Ti), chromium (Cr), tungsten (W), tantalum (Ta), and molybdenum (Mo). Alternatively, the second capacity electrode 16b can be formed of an aluminum (Al) film.

The first capacity electrode 16a is formed of, for example, a conductive polysilicon film, and serves as a pixel potential side capacity electrode of the capacity element 16. Here, the first capacity electrode 16a may be formed of metal or a single layer film or a multilayer film including an alloy, similar to the case of the capacity line 3b. The first capacity electrode 16a has a function of relay-connecting the pixel electrode 27 to the pixel electrode side source drain region 30d (drain region) of the transistor 30 via contact holes CNT1, CNT3, and CNT4, in addition to the function as the pixel potential side capacity electrode.

The data line 6a is formed on the capacity element 16 via a third insulating layer 11c. The data line 6a is electrically connected to the data line side source drain region 30s of the semiconductor layer 30a via the contact hole CNT2 which is open to the gate insulating layer 11g, the second insulating layer 11b, the dielectric film 16c, and the third insulating layer 11c.

The pixel electrode 27 is formed on an upper layer of the data line 6a via a fourth interlayer insulating layer 11d. The fourth interlayer insulating layer 11d is formed of, for example, a silicon nitride or a silicon oxide, and is subjected to a planarization treatment of planarizing a convex portion on the surface that occurs when the region in which the transistor 30 is provided is covered. Examples of a method of the planarization treatment include a chemical mechanical polishing treatment (CMP treatment) and a spin coating treatment. The contact hole CNT4 is formed on the fourth interlayer insulating layer 11d.

The pixel electrode 27 is connected to the first capacity electrode 16a via the contact holes CNT4 and CNT3 so as to electrically be connected to the pixel electrode side source drain region 30d of the semiconductor layer 30a. Note that, the pixel electrode 27 is formed of, for example, a transparent conductive film such as an ITO film.

The first alignment film 28 on which an inorganic material such as oxide silicon (SiO₂) is obliquely deposited is provided on the fourth interlayer insulating layer 11d between the pixel electrodes 27 which are adjacent to each other. The liquid crystal layer 15 in which the liquid crystal or the like is sealed into a space surrounded by the sealing material 14 is provided on the first alignment film 28.

On the other hand, the counter electrode 31 is provided on the entire surface of the insulating layer 33 (the liquid crystal layer 15 side) of the counter substrate 20. The second alignment film 32 on which an inorganic material such as oxide silicon (SiO₂) is obliquely deposited is provided on the counter electrode 31. The counter electrode 31 is formed of, for example, a transparent conductive film such as an ITO film, similar to the pixel electrode 27.

The liquid crystal layer 15 is aligned into a predetermined condition by the alignment films 28 and 32 in a state where an electric filed is not generated between the pixel electrode 27 and the counter electrode 31. The sealing material 14 is an adhesive, which is formed of a photocurable resin, a thermosetting resin, or the like, for bonding the element substrate 10 and the counter substrate 20 to each other, and in which a spacer such as a glass fiber or a glass bead for setting the distance between the element substrate 10 and the counter substrate 20 to be a predetermined value is mixed.

The light of a projector 1000 described below is incident from the rear surface side (element substrate 10 side) of the liquid crystal device 100.

### Structure Around Sealing Material of Liquid Crystal Device

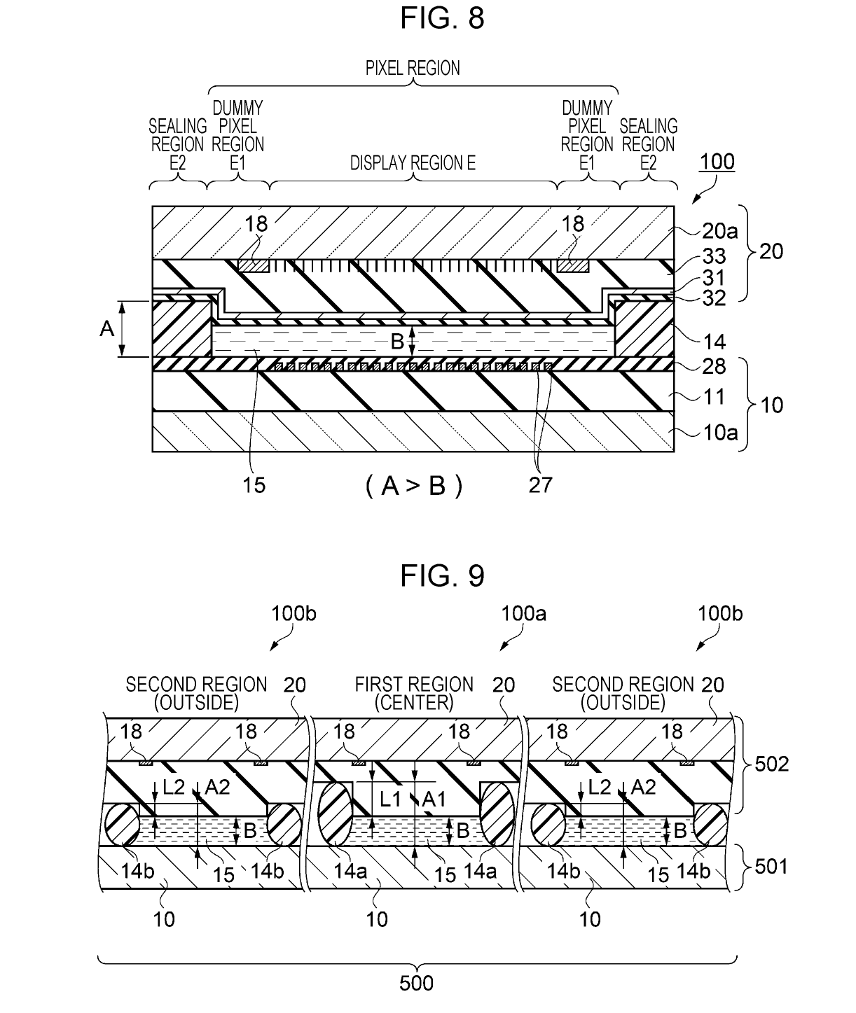

Next, the structure around the sealing material of the liquid crystal device will be described with reference to FIG. 8. FIG. 8 is a sectional view schematically illustrating the structure around the sealing material in the liquid crystal device. Note that, FIG. 8 is illustrated in a simplified form for ease of description.

As illustrated in FIG. 8, the element substrate 10 is provided with the circuit layer 11 in which the TFT 30 and the like are formed on the first material 10a, the pixel electrode 27 formed on the circuit layer 11, and the first alignment film 28 provided on the pixel electrode 27 and the circuit layer 11.

The counter substrate 20 is provided with the light shielding film 18 formed on the second substrate 20a, the insulating layer 33 formed so as to cover the light shielding film 18 and the second substrate 20a, the counter electrode 31 formed so as to cover the insulating layer 33, and the second alignment film 32 formed so as to cover the counter electrode 31.

The element substrate 10 and the counter substrate 20 are bonded to each other via the sealing material 14. Here, the region in which the sealing material 14 is disposed is referred to as a sealing region E2. The region contributing to the display is referred to as the display region E. A region between the display region E and the sealing region E2 is referred to as a dummy pixel region E1. In addition, the display region E and the dummy pixel region E1 are collectively referred to as a pixel region.

Specifically, the thickness (the film thickness) of the insulating layer 33 in the pixel region including the display region E is set to be larger than the thickness (the film thickness) of the insulating layer 33 in the sealing region E2. That is, a cell gap A in the sealing region E2 is larger than a cell gap B of the pixel region (A>B). The size of the cell gap B is in a range of 2 μm to 3 μm, for example. A step portion between A and B is set to be a region in which the sealing material 14 is formed or a region which is not overlapped with the light shielding film 18 in a plan view.

### Structure of Large Substrate

Next, the structure for each regions of the large substrate including the plurality of liquid crystal devices will be described with reference to FIG. 9. FIG. 9 is a schematic sectional view taken along line IX-IX of the large substrate as illustrated in FIG. 2. Specifically, FIG. 9 is a schematic sectional view illustrating the structure of the liquid crystal device in the first region (a central region) of the large substrate, and the structure of the liquid crystal device in the second region (an outside region) of the large substrate. Note that, FIG. 9 is illustrated in a simplified form for ease of description.

As illustrated in FIG. 9, a liquid crystal device 100a in a first region of a large substrate 500 has a step in the sealing region (E2) on the counter substrate 20 side, and the step is larger than that of a liquid crystal device 100b of a second region of the large substrate 500. Note that, a region in which a first sealing material 14a is formed is referred to as a first sealing region. On the other hand, a region in which a second sealing material 14b is formed is referred to as a second sealing region.

Specifically, in the large substrate 500, the density of the sealing material 14 of the first region is larger than that of the second region. In addition, there are a number of regions which are filled with the liquid crystal 15a. Accordingly, when the first large substrate 501 and the second large substrate 502 are bonded to each other, the first sealing material 14a of the first region and the second sealing material 14b of the second region have different amounts of collapse from each other. That is, as compared with the second region, the first sealing material 14a has a high density in the first region, and thus is less likely to collapse. On the other hand, as compared with the first region, the second sealing material 14b has a low density in the second region, and thus is likely to collapse.

With this, in consideration that the first sealing material 14a is less likely to collapse, the step in the first sealing region is set to be large such that the liquid crystal device 100a in the first region can secure a cell thickness B to be a predetermined thickness when the first sealing material 14a collapses.

On the other hand, in consideration that the second sealing material 14b is likely to collapse, the step in the second sealing region is set to be small such that the liquid crystal device 100b in the second region can secure the cell thickness B to be a predetermined thickness when the second sealing material 14b collapses.

Note that, a first step L1 between the display region E in the liquid crystal device 100a (the counter substrate 20 side) in the first region and the sealing region is, for example, 3000 angstrom. A second step L2 between the display region E and the sealing region in the liquid crystal device 100b (the counter substrate 20 side) in the second region is, for example, 2000 angstrom. Further, the gap amount of the region in which the first sealing material 14a is disposed is set to be a first gap amount A1. On the other hand, the gap amount of the region in which the second sealing material 14b is disposed is set to be a second gap amount A2.

### Method of Manufacturing Large Substrate (Liquid Crystal Device)

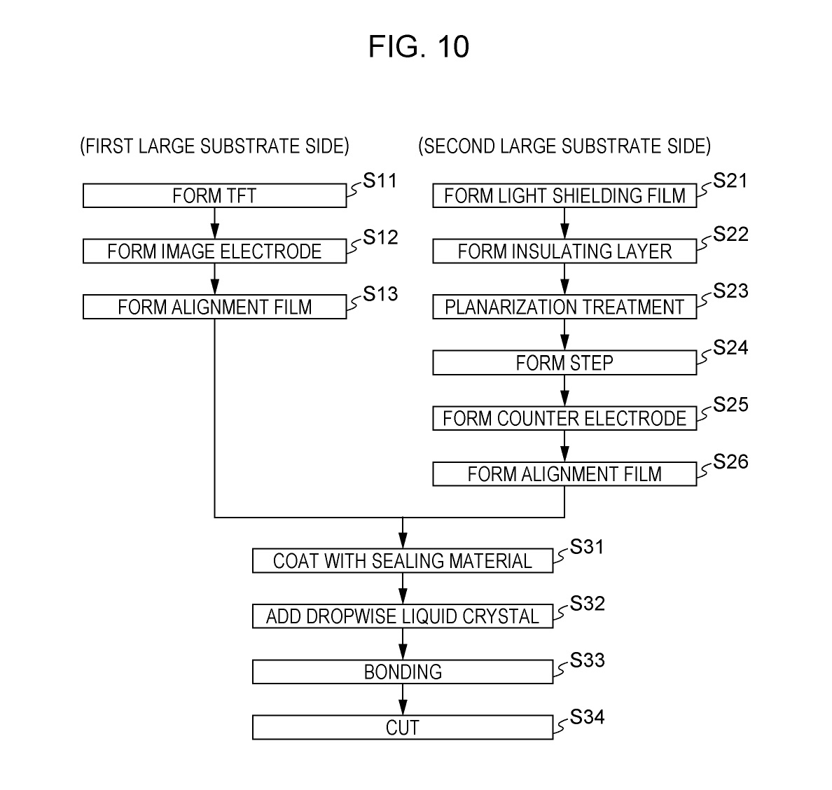

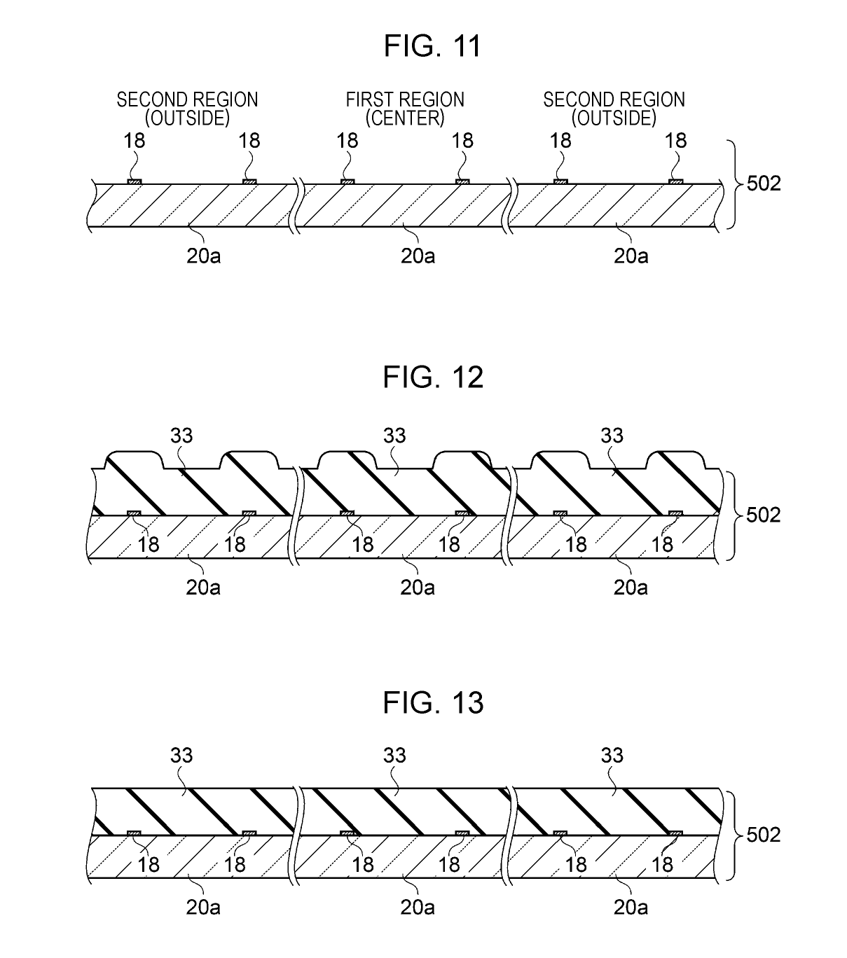

FIG. 10 is a flowchart illustrating a method manufacturing a large substrate (the liquid crystal device) in order of steps. FIGS. 11 to 18 are schematic sectional views illustrating some manufacturing methods among the methods of manufacturing a large substrate. Hereinafter, the method of manufacturing a large substrate will be described with reference to FIGS. 10 to 18.

First, a method of manufacturing of the first large substrate 501 (the element substrate 10) will be described. First, the TFT 30 and the like are formed on the first material 10a which is formed of the quartz substrate in Step S11. Specifically, the light shielding layer 3c, the first insulating layer 11a, the TFT 30, and the like are formed by using a well-known film formation technique, a photolithography technique, and an etching technique.

The pixel electrode 27 is formed in Step S12. As described above, examples of the method of manufacturing include the well-known film formation technique, the photolithography technique, and the etching technique, and the pixel electrode 27 is formed by using these techniques.

The first alignment film 28 is formed in Step S13. Specifically, the first alignment film 28 is formed so as to cover the pixel electrode 27. As the method of manufacturing the first alignment film 28, for example, an oblique deposition method of obliquely depositing an inorganic material such as oxide silicon (SiO₂) is used. With this, the forming of the first large substrate 501 is completed.

Subsequently, a method of manufacturing the second large substrate 502 (the counter substrate 20) will be described. First, the light shielding film 18 is formed on the second substrate 20a which is formed of a translucent material such as a glass substrate in Step S21. Specifically, as illustrated in FIG. 11, the light shielding film 18 is formed by using the well-known film formation technique, the photolithography technique, and the etching technique.

The insulating layer 33 is formed on the light shielding film 18 and the second substrate 20a in Step S22. Specifically, as illustrated in FIG. 12, an oxide silicon film is formed on the second substrate 20a by using, for example, a plasma CVD method. The thickness (the film thickness) of the insulating layer 33 is, for example, 1 μm.

In Step S23, the insulating layer 33 is subjected to a planarization treatment. Specifically, as illustrated in FIG. 13, in order to perform the planarization on the insulating layer 33, for example, the planarization is performed by using the CMP technique. The thickness of the insulating layer 33 after performing the planarization is, for example, 0.5 μm. With this, unevenness of the surface of the insulating layer 33 caused by the thickness of the light shielding film 18 in the lower layer is planarized.

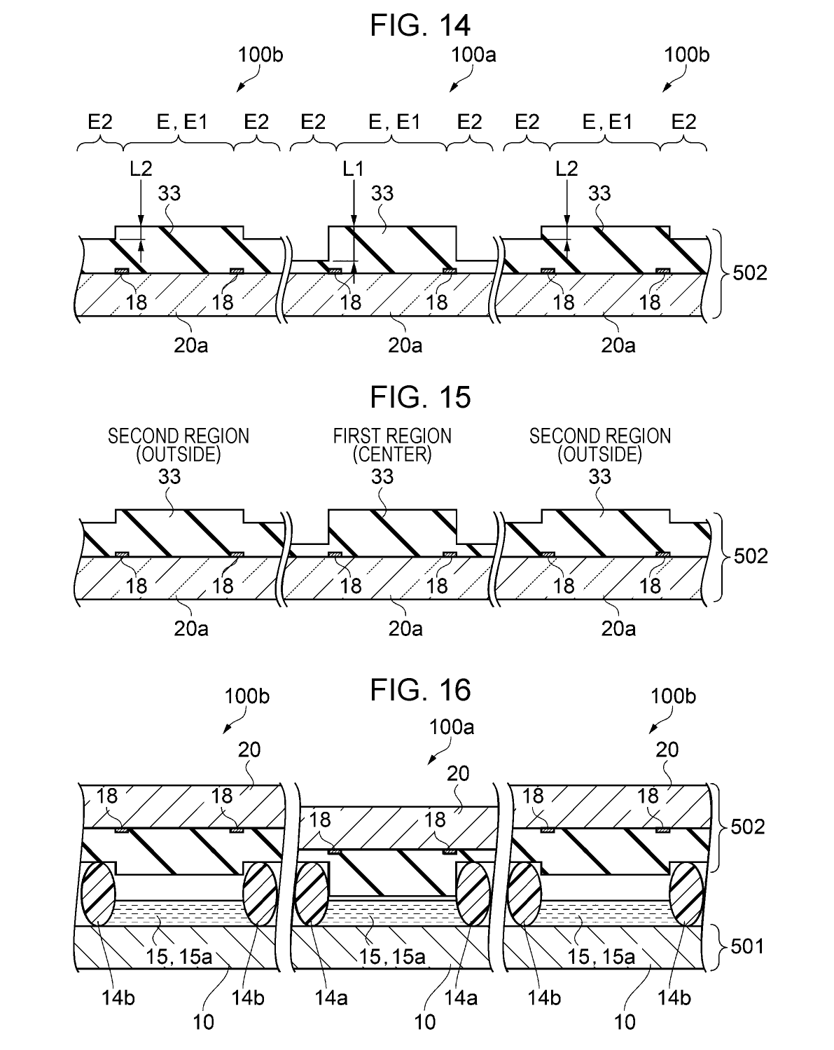

A step is formed on the surface of the insulating layer 33 in Step S24. Specifically, as illustrated in FIG. 14, a portion of the insulating layer 33 in the sealing region E2 is removed through etching, for example. The etching may be wet etching or dry etching.

The first step L1 in the insulating layer 33 of the liquid crystal device 100a in the first region is larger than the second step L2 in the insulating layer 33 of the liquid crystal device 100b in the second region. The thickness (the film thickness) of the insulating layer 33 in the display region E is the same as those in the first region and the second region. As the method of differentiating the steps L1 and L2 form each other, the number of times of using the photolithography technique, the etching technique, and a peeling technique is differentiated.

In the embodiment, the dummy pixel region E1 between the display region E and the sealing region E2 is not subjected to the etching treatment. The first step L1 in the liquid crystal device 100a in the first region is, for example, 3000 angstrom. The second step L2 in the liquid crystal device 100b in the second region is, for example, 2000 angstrom.

The counter electrode 31 is formed so as to cover the insulating layer 33 in Step S25. The second alignment film 32 is formed so as to cover the counter electrode 31 (note that, the counter electrode 31 and the second alignment film 32 are not illustrated in FIG. 15) in Step S26. Specifically, when the counter electrode 31 is formed by using the well-known film formation technique, the counter electrode 31 is formed in accordance with the unevenness of the surface of the insulating layer 33.

In addition, the method of manufacturing the second alignment film 32 is the same as the method of manufacturing the first alignment film 28, and for example, oblique deposition method is used. As described above, the forming of the second large substrate 502 is completed. Next, a method of bonding the first large substrate 501 to the second large substrate 502 will be described.

The first large substrate 501 (the element substrate 10) is coated with the sealing material 14 in Step S31. Specifically, as illustrated in FIG. 16, a relative positional relationship between the first large substrate 501 and a dispenser (a discharge device may be used) is changed so as to coat the periphery portion (the sealing region E2) of the display region E in the element substrate 10 with the sealing material 14. Note that, not only the first large substrate 501 is coated with the sealing material 14 but also the second large substrate 502 may be coated with the sealing material 14.

Examples of the sealing material 14 include a UV-curable epoxy resin. Note that, the sealing material 14 is not limited to a photo-curing resin such as ultraviolet, and a thermosetting resin or the like may be used.

The liquid crystal 15a is added dropwise into the region surrounded by the sealing material 14 in Step S32. Specifically, as illustrated in FIG. 16, the liquid crystal 15a is added dropwise into the region surrounded by the sealing material 14 (an ODF method). In order to add the liquid crystal dropwise, an ink jet head can be used, for example. The amount of the liquid crystal 15a to be added dropwise is constant for each cell.

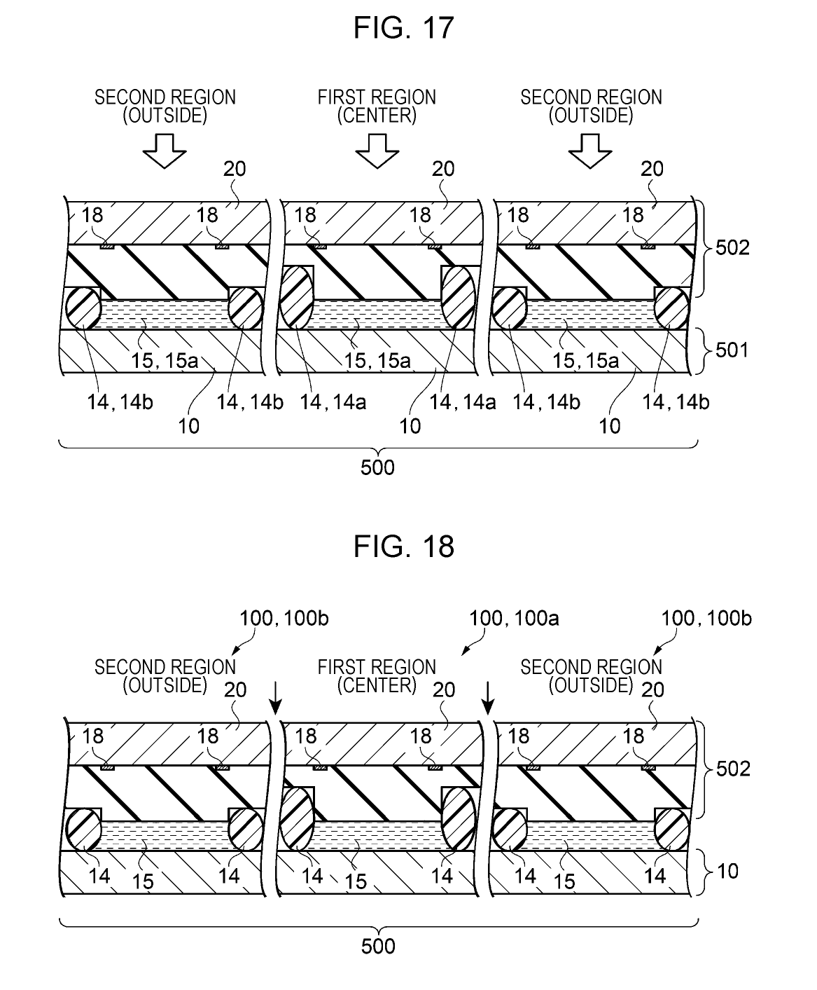

The first large substrate 501 and the second large substrate 502 are bonded to each other in Step S33. Specifically, as illustrated in FIG. 17, the first large substrate 501 (the element substrate 10) and the second large substrate 502 (the counter substrate 20) are bonded to each other via the sealing material 14 with which the first large substrate 501 is coated. As described above, the formed of the large substrate 500 is completed.

As the related art, when a certain capacity of the liquid crystal 15a is added dropwise into the region surrounded by the sealing material 14, the sealing material 14 has collapsed unevenly depending on the region of the large substrate 500 and thus the shape of the gap is also unevenly formed.

However, as described in the embodiment, in the liquid crystal device 100a in the first region of the large substrate 500, and the liquid crystal device 100b in the second region of the large substrate 500, when the steps L1 and L2 in the insulating layer 33 are differentiated from each other, even in a case where the amounts of collapse of the sealing materials 14 (14a and 14b) in the first region and the second region of the large substrate 500, it is possible to make the cell thickness B of the liquid crystal device 100a in the first region and the cell thickness B of the liquid crystal device 100b in the second region substantially the same as each other at the time of bonding the first large substrate 501 and the second large substrate 502 to each other.

Specifically, in the related art, the variation between the cell gaps in the liquid crystal devices in the first region and the second region in the large substrate is, for example, 0.28 μm; whereas, in the embodiment, the variation between the cell gaps in the liquid crystal devices 100 (100a and 100b) is, for example, 0.16 μm.

The plurality of liquid crystal devices 100 are formed by cutting the large substrate 500 in Step S34. Specifically, for example, a slit is formed between the liquid crystal devices 100 (100a and 100b) which are adjacent to each other, and after that, force is applied to the surface opposite to the surface on which the slit is formed such that the large substrate 500 is broken. With this, as illustrated in FIG. 18, the plurality of liquid crystal devices 100 are separated from the large substrate 500, and thereby the forming of the liquid crystal device 100 is completed.

### Configuration of Electronic Apparatus

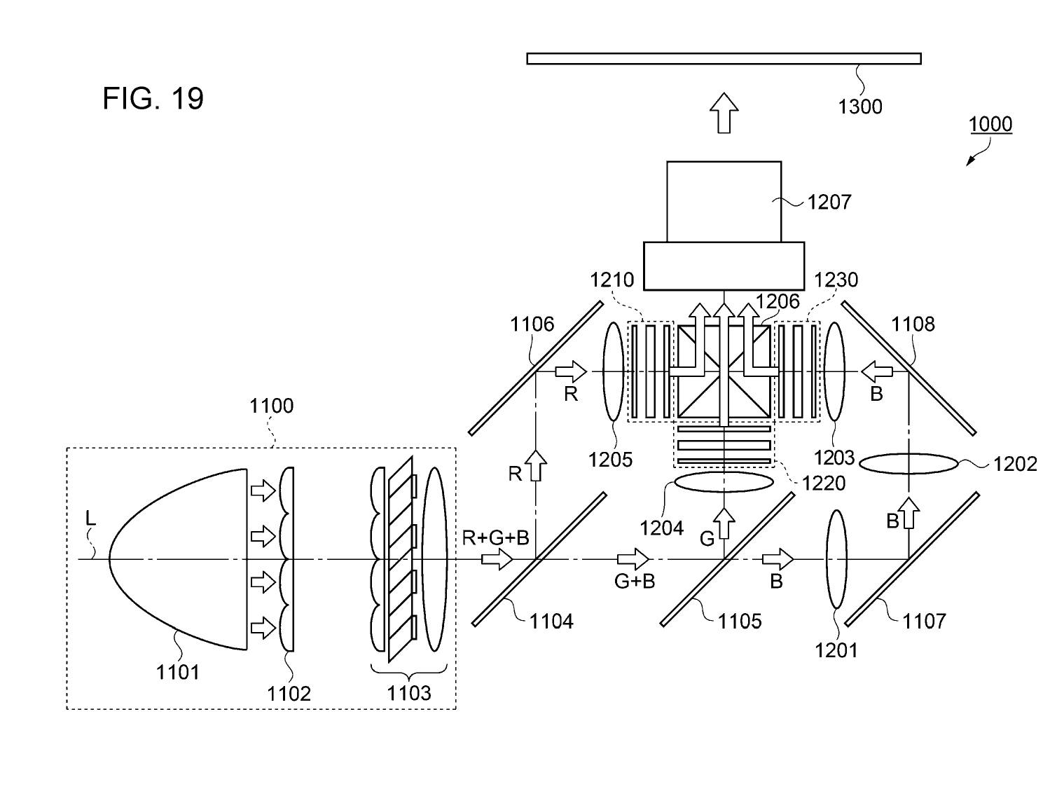

FIG. 19 is a diagram schematically illustrating a configuration of a projector as an electronic apparatus. Hereinafter, the configuration of the projector will be described with reference to FIG. 19.

As illustrated in FIG. 19, the projector 1000 of the embodiment is provided with a polarized illumination device 1100 as an illumination system which is disposed along a system optical axis L, two dichroic mirrors 1104 and 1105 as light separating elements, three reflecting mirrors 1106, 1107, and 1108, five relay lenses 1201, 1202, 1203, 1204, and 1205, transmissive type liquid crystal light bulbs 1210, 1220, and 1230 as three optical modulation means, a cross dichroic prism 1206 as a photosynthesis element, and a projection lens 1207.

The polarized illumination device 1100 is schematically configured to include a lamp unit 1101 as a light source formed of a white light source such as an ultrahigh pressure mercury lamp or a halogen lamp, an integrator lens 1102, and a polarized conversion element 1103.

The dichroic mirror 1104 reflects red light (R) among polarized light beams emitted from the polarized illumination device 1100 and causes green light (G) and blue light (B) to transmit therethrough. Another dichroic mirror 1105 reflects the green light (G) having transmitted through the dichroic mirror 1104 and causes the blue light (B) to transmit therethrough.

The red light (R) having transmitted through the dichroic mirror 1104 is reflected on the reflecting mirror 1106, and then incident on the liquid crystal light bulb 1210 via the relay lens 1205. The green light (G) reflected on the dichroic mirror 1105 is incident on the liquid crystal light bulb 1220 via the relay lens 1204. The blue light (B) having transmitted through the dichroic mirror 1105 is incident on the liquid crystal light bulb 1230 via a light guide system which is formed of three of the relay lenses 1201, 1202, and 1203 and two of the reflecting mirrors 1107 and 1108.

Each of the liquid crystal light bulbs 1210, 1220, and 1230 is disposed to face an incident surface of each light of the cross dichroic prism 1206. Each light incident on the liquid crystal light bulbs 1210, 1220, and 1230 is modulated based on video information (a video signal) so as to be emitted to the cross dichroic prism 1206.

The aforementioned prism has a configuration in which four right-angle prisms are bonded to each other, and a dielectric multilayer for reflecting the red light and a dielectric multilayer for reflecting the blue light are formed in the inside in a cross shape. The red light, the blue light, and the green light are combined with each other by the dielectric multilayer so as to display a color image. The combined light is projected onto a screen 1300 through the projection lens 1207 such that the image is enlarged and displayed.

The liquid crystal device 100 which is described below is applied to the liquid crystal light bulb 1210. The liquid crystal device 100 is disposed with a gap between a pair of the polarizing elements which are arranged in a crossed Nicol state, on the incident side and the emitted side of the color light. The same is true for other liquid crystal light bulbs 1220 and 1230.

The electronic apparatus having the above-described configuration uses the liquid crystal device 100 of the above-described embodiment, and thus it is possible to provide the projector 1000 with high reliability and excellent display properties.

In addition, in addition to the projector 1000, examples of the electronic apparatus to which the liquid crystal device 100 is mounted include various electronic devices such as a head-mounted display (HMD), a head-up display (HUD), a smart phone, an electrical view finder (EVF), a cellular telephone, a mobile computer, a digital camera, a digital video camera, a vehicle device, and a lighting device.

As described in detail above, according to the method of manufacturing the large substrate 500 and the large substrate 500 of the first embodiment, it is possible to obtain the following effects.

(1) According to the large substrate 500 and the method of manufacturing the large substrate 500 of the first embodiment, the gap amounts A (A1 and A2) of the sealing materials 14 (the first sealing material 14a and the second sealing material 14b) are differentiated in the first region and the second region of the large substrate 500, and thus when the first large substrate 501 and the second large substrate 502 are bonded to each other, even in a case where the sealing materials 14 (14a and 14b) have collapsed unevenly due to the density difference of the sealing materials 14 (14a and 14b) or the presence or absence of the liquid crystal layer 15, it is possible to prevent the cell gaps B (shape of the gaps) from being unevenly formed in the display regions of the liquid crystal device 100a in the first region and the liquid crystal device 100b in the second region.

(2) According to the large substrate 500 and the method of manufacturing the large substrate 500 of the first embodiment, the first gap amount and the second gap amount are differentiated from each other by providing the steps L1 and L2 in the region in which the sealing materials 14 (14a and 14b) of the second large substrate 502 are disposed, and thus it is possible to differentiate the gap amounts A1 and A2 from each other in a relatively easy manner.

(3) According to the large substrate 500 and the method of manufacturing the large substrate 500 of the first embodiment, the amount of the first step L1 is larger than that of the second step L2, and thus, for example, even in a case where the first sealing material 14a is less likely to collapse as compared with the second sealing material 14b due to the density difference of the sealing material 14 or the presence or absence of the liquid crystal layer 15, it is possible to prevent the cell gap of the liquid crystal device 100a in the first region and the cell gap of the liquid crystal device 100b in the second region.

(4) According to the large substrate 500 and the method of manufacturing the large substrate 500 of the first embodiment, the first gap amount A1 and the second gap amount A2 are adjusted by setting the film thickness of the display region E to be smaller than the film thickness of the sealing region E2, and thus it is possible to set the amount of the cell gap B to be relatively small. Further, as compared with a case where the display region E is formed to be small, it is possible to prevent the display region E from being damaged, and prevent the display quality from being deteriorated.

### Second Embodiment

### Structure of Large Substrate

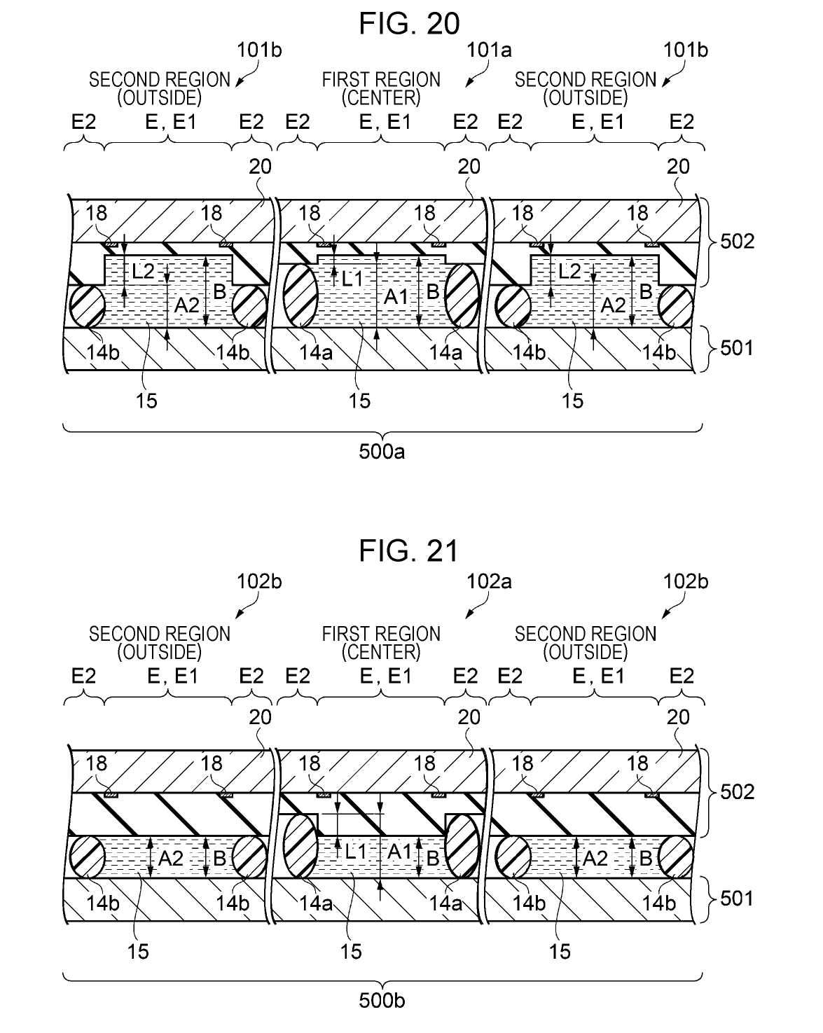

Next, the structure for each regions of the large substrate of the second embodiment will be described with reference to FIG. 20. FIG. 20 is a schematic sectional view taken along line XX-XX of the large substrate as illustrated in FIG. 2, in the second embodiment. Specifically, FIG. 20 is a schematic sectional view illustrating the structure of the liquid crystal device in the first region of the large substrate, and the structure of the liquid crystal device in the second region of the large substrate. Note that, FIG. 20 is illustrated in a simplified form for ease of description.

The large substrate 500a of the second embodiment is substantially the same as the large substrate 500 of the above-described first embodiment except for a portion of the display region E in which the step is provided is different from that in the first embodiment. For this reason, in the second embodiment, portions which are different from those in the first embodiment are described in detail, and the description for other repeated portions will be appropriately omitted.

As illustrated in FIG. 20, in the large substrate 500a of the second embodiment, the configuration of the first large substrate 501 (the element substrate 10) is the same as that of the first embodiment. On the other hand, the configuration of the second large substrate 502 (counter substrate 20) is different from that of the first embodiment in that the shapes of the insulating layer 33, the counter electrode 31, and the second alignment film 32.

Specifically, the insulating layer 33 in the display region E is engraved such that the thickness of the insulating layer 33 in the pixel region including the display region E is smaller than the thickness of the insulating layer 33 in the sealing region E2.

Further, as illustrated in FIG. 20, in the large substrate 500a, the step L2 in the display region E on the counter substrate 20 side of a liquid crystal device 101b in the second region is large as compared with a liquid crystal device 101a of the first region.

Specifically, similar to the first embodiment, in the large substrate 500a, the density of the sealing material 14 of the first region is larger than that of the second region. Accordingly, when the first large substrate 501 and the second large substrate 502 are bonded to each other, the amounts of collapse of the sealing materials 14 of the first region and the second region are different from each other. That is, as compared with the second region, the sealing material 14 has a high density in the first region, and thus is less likely to collapse. On the other hand, as compared with the first region, the sealing material 14 has a low density in the second region, and thus is likely to collapse.

With this, in consideration that the second sealing material 14b is less likely to collapse, the step L2 in the display region E is set to be large such that the liquid crystal device 101b in the second region can secure a cell thickness B to be a predetermined thickness when the second sealing material 14b collapses.

On the other hand, in consideration that the first sealing material 14a is less likely to collapse, the first step L1 in the display region E is set to be small such that the liquid crystal device 101a in the first region can secure the cell thickness B to be a predetermined thickness when the first sealing material 14a collapses.

In addition, the first gap amount A1 and the second gap amount A2 are adjusted by setting the film thickness of the display region E to be small, and thus it is possible to set the film thickness of the substrate in the display region E to be small. Accordingly, it is possible to improve the transmittance in the display region.

When such a second large substrate 502 (the counter substrate 20) is formed, it is possible to set a desired cell gap B at the time of bonding the first large substrate 501 and the second large substrate 502 to each other. Further, as compared with the first embodiment, the thickness of the insulating layer 33 in the sealing region E2 is large, and thus it is possible to not only obtain a desired cell gap B and but also improve moisture resistance.

### Method of Manufacturing Large Substrate (Liquid Crystal Device)

Next, a method of manufacturing a large substrate (the liquid crystal device) of the second embodiment will be described. The method of manufacturing a large substrate (the liquid crystal device) of the second embodiment is substantially the same as different from the method of manufacturing a large substrate of the above-described first embodiment except for the method of forming the insulating layer.

For this reason, in the second embodiment, portions which are different from those in the first embodiment are described in detail, and the description for other repeated portions will be appropriately omitted. In addition, the method of manufacturing a large substrate of the second embodiment will be described with reference to FIGS. 10 to 18 used in the first embodiment.

As illustrated in FIGS. 10 to 13, regarding the method of manufacturing the large substrate 500a (the liquid crystal device 101) of the second embodiment, Steps S11 to Step S13, and Steps S21 to Step S23 are the same as those in the first embodiment.

A step is formed on the surface of the insulating layer 33 in Step S24. Specifically, a portion of the insulating layer 33 in the display region E and the first sealing region is removed through an etching treatment or the like. The first step L1 in the insulating layer 33 of the liquid crystal device 101a in the first region is smaller than the second step L2 in the insulating layer 33 of the liquid crystal device 101b in the second region. The thickness of the insulating layer 33 in the display region E is the same as the thickness of that in the first region and the second region. As the method of differentiating the steps L1 and L2 form each other, the number of times of using the photolithography technique, the etching technique, and a peeling technique is differentiated.

In the embodiment, the dummy pixel region E1 between the display region E and the sealing region is subjected to the etching treatment. The first step L1 in the liquid crystal device 101a in the first region is, for example, 2000 angstrom. The second step L2 in the liquid crystal device 101b in the second region is, for example, 3000 angstrom.

Hereinafter, from Step S25 to Step S34, the large substrate is manufactured in the same way as in the first embodiment. In addition, in the liquid crystal device 101a in the first region of the large substrate 500a, and the liquid crystal device 101b in the second region of the large substrate 500a, when the steps L1 and L2 in the insulating layer 33 are differentiated from each other, even in a case where the amounts of collapse of the sealing materials 14a and 14b in the first region and the second region of the large substrate 500, it is possible to make the cell thickness B of the liquid crystal device 101a in the first region and the cell thickness B of the liquid crystal device 101b in the second region substantially the same as each other at the time of bonding the first large substrate 501 and the second large substrate 502 to each other in Step S33.

Lastly, the forming of a plurality of the liquid crystal devices 101 is completed by cutting the large substrate 500a in Step S34 (refer to FIG. 20).

As described in detail above, according to the method of manufacturing the large substrate 500 and the large substrate 500 of the second embodiment, it is possible to obtain the following effects in addition to the effects of the above-described embodiment.

(5) According to the large substrate 500 and the method of manufacturing the large substrate 500 of the second embodiment, in the second large substrate 502, the first gap amount A1 and the second gap amount A2 are adjusted by setting the film thickness of the display region E to be small, and thus it is possible to set the film thickness of the substrate in the display region E to be small. Accordingly, it is possible to improve the transmittance in the display region E.

### Third Embodiment

### Structure of Large Substrate

Next, the structure for each region of the large substrate in the third embodiment will be described with reference to FIG. 21. FIG. 21 is a schematic sectional view taken along line XXI-XXI of the large substrate as illustrated in FIG. 2, in the third embodiment. Specifically, FIG. 21 is a schematic sectional view illustrating the structure of the liquid crystal device in the first region of the large substrate, and the structure of the liquid crystal device in the second region of the large substrate. Note that, FIG. 21 is illustrated in a simplified form for ease of description.

The large substrate 500b of the third embodiment is substantially the same as the large substrate 500 of the above-described first embodiment except for a portion of the liquid crystal device 102b in the second region in which the step L2 is not provided is different from that in the first embodiment. For this reason, in the third embodiment, portions which are different from those in the first embodiment are described in detail, and the description for other repeated portions will be appropriately omitted.

As illustrated in FIG. 21, in the large substrate 500b of the third embodiment, the configuration of the first large substrate 501 (the element substrate 10) is the same as that of the first embodiment. In addition, a configuration of a liquid crystal device 102a in the first region of the second large substrate 502 (the counter substrate) is the same as that in the first embodiment.

On the other hand, in a configuration of the liquid crystal device 102b in the second region of the second large substrate 502, the step is not provided in the display region E (E1) and the sealing region E2. That is, the surface of the second large substrate 502 on the liquid crystal layer 15 is flat.

Specifically, the insulating layer 33 in the sealing region E2 of the liquid crystal device 102a in the first region is engraved such that the thickness of the insulating layer 33 in the sealing region E2 is smaller than the thickness of the insulating layer 33 in the display region E. On the other hand, the insulating layer 33 in the display region E and the sealing region E2 of the liquid crystal device 102b in the second region is not engraved.

Specifically, similar to the first embodiment and the second embodiment, in the large substrate 500b, the density of the sealing material 14 of the first region is larger than that of the second region. Accordingly, when the first large substrate 501 and the second large substrate 502 are bonded to each other, the first sealing material 14a of the first region and the second sealing material 14b of the second region have different amounts of collapse from each other. That is, as compared with the second region, the first sealing material 14a of the liquid crystal device 102a has a high density in the first region, and thus is less likely to collapse. On the other hand, as compared with the first region, the second sealing material 14b of the liquid crystal device 102b has a low density in the second region, and thus is likely to collapse.

With this, in consideration that the second sealing material 14b is likely to collapse, the surface of the counter substrate 20 is set to flat such that the liquid crystal device 102b in the second region can secure a cell thickness B to be a predetermined thickness when the second sealing material 14b collapses.

On the other hand, in consideration that the first sealing material 14a is less likely to collapse, the first step L1 in the sealing region E2 is set to be small such that the liquid crystal device 102a in the first region can secure the cell thickness B to be a predetermined thickness when the first sealing material 14a collapses.

In addition, the first step L1 of the liquid crystal device 102a in the first region is, for example, 1000 angstrom. The step is not provided in the liquid crystal device 102b in the second region.

When such a second large substrate 502 (the counter substrate 20) is formed, it is possible to set a desired cell gap B at the time of bonding the first large substrate 501 and the second large substrate 502 to each other. Further, as compared with the first embodiment, the thickness of the insulating layer 33 in the sealing region E2 is large, and thus it is possible to not only obtain a desired cell gap B and but also improve moisture resistance.

### Method of Manufacturing Large Substrate (Liquid Crystal Device)

Next, a method of manufacturing a large substrate (the liquid crystal device) of the third embodiment will be described. The method of manufacturing a large substrate of the third embodiment is substantially the same as different from the method of manufacturing a large substrate of the above-described first embodiment except for the method of forming the insulating layer.

For this reason, in the third embodiment, portions which are different from those in the first embodiment are described in detail, and the description for other repeated portions will be appropriately omitted. In addition, the method of manufacturing a large substrate of the second embodiment will be described with reference to FIGS. 10 to 18 used in the first embodiment.

As illustrated in FIGS. 10 to 13, regarding the method of manufacturing the large substrate 500b (the liquid crystal device 102) of the third embodiment, Steps S11 to Step S13, and Steps S21 to Step S23 are the same as those in the first embodiment.

A step is formed on the surface of the insulating layer 33 of the liquid crystal device 102a in the first region in Step S24. Specifically, similar to the first embodiment, a portion of the insulating layer 33 is removed by performing the etching treatment on the sealing region E2. Note that, the insulating layer 33 of the liquid crystal device 102b in the second region is not subjected to the etching treatment. The thickness of the insulating layer 33 in the display region E is the same as those of the liquid crystal device 102a in the first region and the liquid crystal device 102b in the second region.

In addition, the first step L1 of the liquid crystal device 102a in the first region is, for example, 1000 angstrom. The step L2 is not provided in the liquid crystal device 102b in the second region.

Hereinafter, from Step S25 to Step S34, the large substrate is manufactured in the same way as in the first embodiment. Specifically, in the liquid crystal device 102a in the first region of the large substrate 500, when the thickness of the insulating layer 33 in the sealing region E2 is formed to be small, even in a case where the amounts of collapse of the sealing materials 14a and 14b in the first region and the second region of the large substrate 500, it is possible to make the cell thickness B of the liquid crystal device 102a in the first region and the cell thickness B of the liquid crystal device 102b in the second region substantially the same as each other at the time of bonding the first large substrate 501 and the second large substrate 502 to each other in Step S33.

Lastly, the forming of a plurality of the liquid crystal devices 102 is completed by cutting the large substrate 500b in Step S34 (refer to FIG. 21).

As described in detail above, according to the method of manufacturing the large substrate 500 and the large substrate 500 of the third embodiment, it is possible to obtain the following effects in addition to the effects of the above-described embodiment.

(6) According to the large substrate 500 of third embodiment, in the large substrate 500, the film thickness of the region in which at least the first sealing material 14a in the first region is disposed may be small, and the step may not be provided in the region in which the second sealing material 14b in the second region is disposed step. With this, the step may be formed only in the first region, and thus it is possible to suppress cost to form the step. In addition, the region for forming the step may be small, and thus it is possible to prevent the gap amount from being varied.

Note that, the aspects of the invention are not limited to the above-described embodiments. For example, the embodiments can be appropriately modified without departing from the essence or spirit of the invention read from the claims and the entire specification and are included within the scope of aspects of the invention. Further, it may also be implemented in the following aspects.

### MODIFICATION EXAMPLE 1

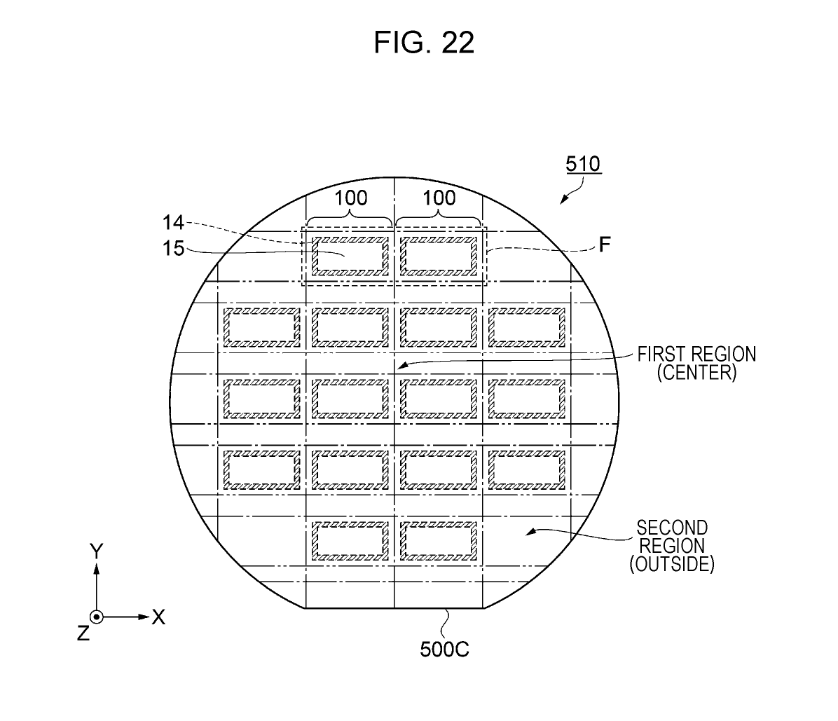

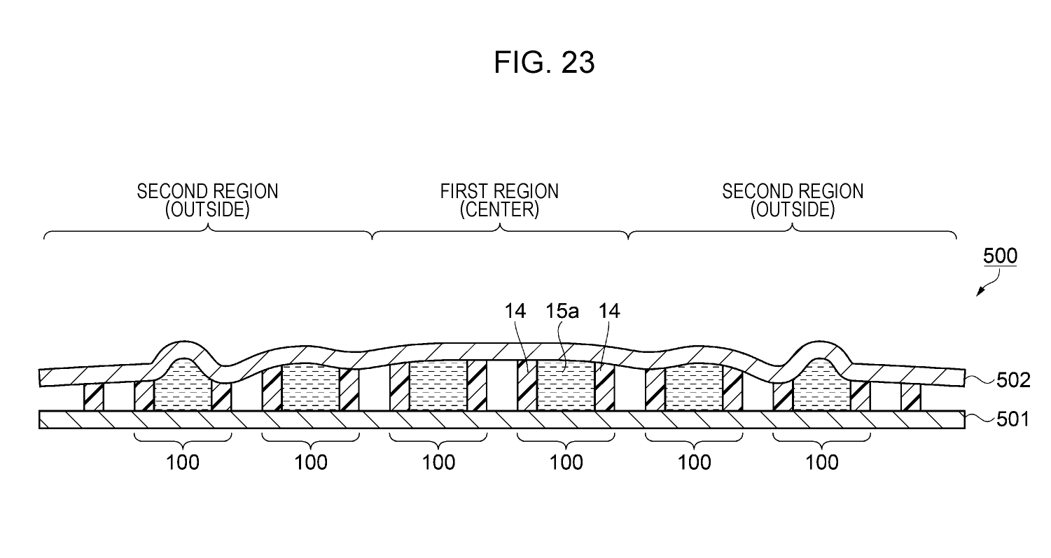

As described above, the step is not necessarily provided in the entire second region. For example, the step may be provided in the region illustrated in FIG. 22. FIG. 22 is a plan view schematically illustrating the large substrate when seen from above in a modification example. As illustrated in FIG. 22, regarding a large substrate 510 of the modification example, the step is provided only in a region F on the side opposite to an orientation flat 500c. Specifically, the step is formed in two liquid crystal devices 100 (two chips) in the region F as described above.

With this, even in a case where the sealing material 14 partially collapses in the large substrate 510, or the sealing material 14 is less likely to collapse, it is possible to correct the gap amount, and thereby it is possible to form the liquid crystal device 100 having a uniform gap amount on the entire large substrate 510. Note that, the region F is described in the above; however, the region is not limited thereto. For example, the step may be provided in the liquid crystal device 100 in a desired region.

In addition, the step is not necessarily provided as in the above-described embodiments and modification examples. For example, in accordance with the situation of the variation between cell gaps in the large substrate 500, the step may be provided only in the liquid crystal device, or in a case where the step is provided in each of the liquid crystal devices on the entire large substrate 500, the amount of the step only in a certain liquid crystal device may be different from the among of the steps in other liquid crystal devices.

### MODIFICATION EXAMPLE 2

As described above, the steps in two regions of the first region and the second region on the large substrate 500 are not necessarily different from each other. For example, the amount of the step may be gradually changed as being directed to outside of the second region from the center of the first region.

With this, the amount of the step is gradually changed, and thus it is possible to change the amount of deformation depending on the region of the large substrate 500, and it is possible to set the cell gap B to be constant on the entire large substrate 500.

### MODIFICATION EXAMPLE 3

As described above, the step is not necessarily provided only on the second large substrate 502 (the counter substrate 20) side. For example, the step may be provided on the first large substrate 501 (the element substrate 10) side. In addition, the step may be provided on both of the first large substrate 501 and the second large substrate 502.

### MODIFICATION EXAMPLE 4

Similar to the above-described third embodiment, the step is not necessarily provided only in the sealing region E2 of the liquid crystal device 102a in the first region. For example, the step is not provided in the liquid crystal device 102a in the first region, but the step may be provided in the display region of the liquid crystal device 102b in the second region such that the display region becomes concave.

The entire disclosure of Japanese Patent Application No. 2016-067496, filed Mar. 30, 2016 is expressly incorporated by reference herein.

What is claimed is:

1. A large substrate comprising:
a first large substrate which is provided with a plurality of first substrates;
a second large substrate which is provided with a plurality of second substrates;
a sealing material which is disposed between the first large substrate and the second large substrate which are disposed to face each other; and
a liquid crystal layer which is disposed by being surrounded by the sealing material,
wherein in a certain region, a gap amount of a display region and a gap amount of a region in which the sealing material is provided are different from each other on the first substrate and the second substrate.

2. The large substrate according to claim 1,
wherein the gap amount of the display region and the gap amount of the region in which the sealing material is provided are different from each other on the entire first large substrate and the second large substrate, and
wherein the gap amount of the region, in which the sealing material is provided, in the certain region is different from of the gap amount of the region, in which the sealing material is provided, in a region other than the certain region.

3. A large substrate comprising:
a first large substrate which is provided with a plurality of first substrates;
a second large substrate which is provided with a plurality of second substrates;
a sealing material which is disposed between the first large substrate and the second large substrate which face each other; and
a liquid crystal layer which is disposed by being surrounded by the sealing material,
wherein the sealing material includes at least a first sealing material which is disposed between the first substrate and the second substrate in a central region of the first large substrate and the second large substrate, and a second sealing material which is disposed between the first substrate and the second substrate in an outside region of the first large substrate and the second large substrate, and
wherein when a cell gap in a display region of the first substrate and the second substrate in the central region and the outside region is set to be constant, a gap amount of a region in which the first sealing material is provided and a gap amount of at least a portion of a region in which the second sealing material is provided are different from each other.

4. The large substrate according to claim 1,
wherein the gap amount is formed by providing a step in at least one of the first substrate and the second substrate.

5. The large substrate according to claim 4,
wherein the step includes a first step which is provided in the region in which the first sealing material is disposed, and a second step which is provided in the region in which the second sealing material is disposed, and
wherein an amount of the first step is larger than that of the second step.

6. The large substrate according to claim 4,
wherein the step includes a first step which is provided in the region in which the first sealing material is disposed, and a second step which is provided in the region in which the second sealing material is disposed, and
wherein an amount of the first step is smaller than that of the second step.

7. The large substrate according to claim 3,
wherein the first large substrate and the second large substrate include a sealing region in which the first sealing material and the second sealing material are provided, and a display region which is surrounded by the sealing region, and
wherein a film thickness of an insulating layer in the sealing region is smaller than a film thickness of an insulating layer in the display region.

8. The large substrate according to claim 3,
wherein the first large substrate and the second large substrate include a sealing region in which the first sealing material and the second sealing material are provided, and a display region which is surrounded by the sealing region, and
wherein a film thickness of an insulating layer in the display region is smaller than a film thickness of an insulating layer of the sealing region.

9. The large substrate according to claim 3,
wherein the first large substrate and the second large substrate include a sealing region in which the first sealing material and the second sealing material are provided, and a display region which is surrounded by the sealing region, and
wherein a film thickness of an insulating layer in a first sealing region in which at least the first sealing material is provided to be smaller than a film thickness of an insulating layer in the display region.

10. The large substrate according to claim 3,
wherein in the first large substrate and the second large substrate, the amount of the step gradually changes from the central region to the outside region.

11. A method of manufacturing a large substrate, comprising:
coating a first large substrate which is provided with a plurality of first substrates with a sealing material;
adding a liquid crystal dropwise into a region surrounded by the sealing material;
bonding the first large substrate and a second large substrate which is provided with a plurality of second substrates to each other; and
forming a step in at least one of the first substrate and the second substrate before coating the first large substrate with the sealing material.

12. A method of manufacturing a large substrate, comprising:
coating a central region of a first large substrate which is provided with a plurality of first substrates with a first sealing material;
coating an outside region of the first large substrate with a second sealing material;
adding a liquid crystal dropwise into a region surrounded by the first sealing material and the second sealing material;
bonding the first large substrate and a second large substrate which is provided with a plurality of second substrates to each other; and
forming a step in at least one of the first substrate and the second substrate before coating the first large substrate with the first sealing material such that a gap amount of a region which is coated with the first sealing material and a gap amount of at least a portion of the region which is coated with the second sealing material are different from each other in a case where a cell gap in a display region of the first substrate and the second substrate is set to be constant.

13. The method of manufacturing a large substrate according to claim 12,
wherein in the forming of the step, the step is formed in at least one substrate of the first substrate and the second substrate by removing a portion of the region which is coated with the first sealing material and the second sealing material.

14. The method of manufacturing a large substrate according to claim 12,
wherein in the forming of the step, the step is formed in at least one substrate of the first substrate and the second substrate by removing a portion of the display region.
